(19) United States
(12) Patent Application Publication
(10) Pub. No.: US 2025/0202195 A1
(43) Pub. Date: Jun. 19, 2025

(54) LASER LIGHT SOURCE

(71) Applicant: KYOCERA SOC Corporation, Yokohama (JP)

(72) Inventors: Masami Hatori, Yokohama (JP); Kenji Ohara, Yokohama (JP)

(21) Appl. No.: 18/944,667

(22) Filed: Nov. 12, 2024

(30) Foreign Application Priority Data
Dec. 14, 2023 (JP) 2023-210841

(51) Int. Cl. H01S 5/0687; H01S 5/00; H01S 5/14; H01S 5/323

(52) U.S. Cl. CPC H01S 5/0687; H01S 5/0078; H01S 5/142; H01S 5/32341

(57) ABSTRACT

A laser light source that is able to achieve stable light output by suppressing unwanted oscillation is disclosed. In a laser light source, using a semiconductor laser, as a light source, a light detector that detects light output from the semiconductor laser, a feedback circuit that receives a signal output from the light detector and sets a drive current of the semiconductor laser so that the light output indicated by the signal is within a target region and a control circuit that sets the target region between a light output P2 and a light output P1 smaller than the light output P2 are provided.

### CROSS REFERENCE TO RELATED APPLICATIONS

The present application claims priority under 35 U.S.C. § 119 to Japanese Patent Application No. 2023-210841, filed on Dec. 14, 2023. The above application is hereby expressly incorporated by reference, in its entirety, into the present application.

### BACKGROUND

The present disclosure relates to a laser light source, and particularly to a laser light source adopting a semiconductor laser as a light source.

Conventionally, for example, as disclosed in Japanese Patent No. 7086537 (Document 1) and Japanese Unexamined Patent Publication No. 2010-51503 (Document 2), a laser light source using a semiconductor laser (laser diode), as a light source, is known. This kind of laser light source is often used as a light source for measurement in various kinds of measurement devices, and especially in such a case, the light output needs to be kept within a certain fixed range.

To satisfy such a need, APC (Automatic Power Control) has been often performed, as disclosed also in Document 1. The APC detects light output from a laser light source by a light detector, such as a PD (Photo Diode), and controls the light output so as to be within a fixed range by increasing or decreasing a drive current of a semiconductor laser based on a value of the detected light output. Document 1 also discloses the feature that an external resonator for feeding back laser light output from a semiconductor laser thereto by selecting the wavelength of the laser light output from the semiconductor laser is provided in addition to a resonator originally constituting the semiconductor laser.

As a technique for setting light output from the semiconductor laser within a fixed range, besides the aforementioned APC, a technique of ACC (Automatic Current Control) disclosed in paragraph of Document 2 is also known. The ACC controls the drive current flowing into the semiconductor laser so as to be constant. In this case, it is also necessary to control the temperature of the semiconductor laser at high accuracy to prevent a fluctuation of light output caused by a fluctuation of temperature.

### SUMMARY

Since a laser light source adopting a semiconductor laser performing the APC normally has a desirable characteristic that a light output value and a drive current value have one to one correspondence, such a laser light source has been widely used. However, when a circuit loop is formed, a problem that oscillation occurs at a high speed control is recognized. A stable control of light output is possible by avoiding this problem as long as a high speed circuit loop is not formed. However, especially when the laser light source has the aforementioned external resonator, an electric current region exists where a light output value and a drive current value fail to have one to one correspondence and two light output values correspond to one drive current value. Therefore, stable control of light output is not possible, and unwanted oscillation may be induced. If unwanted oscillation occurs, an optical noise increases and a problem that a stable laser light source is not obtainable arises.

Next, with reference to FIGS. 5 and 6, this problem will be described. FIG. 5 shows a relationship between the semiconductor laser drive current value (horizontal axis) and light output (vertical axis) when APC is performed, for example. If APC is performed normally, the light output should monotonously increase as the drive current value increases in this relationship, but instead, oscillation may occur in actual cases. As shown in FIG. 6, the oscillation is a phenomenon where the light output changes stepwise between P1 and P2 with respect to a certain drive current value 1op1.

In Document 1, this phenomenon is also described with reference to FIG. 12 of Document 1. FIG. 12 of Document 1 shows that the light output, represented in the vertical axis, may change stepwise between 45 mW and a greater value than this value when the drive current value, represented in the horizontal axis, is near 200 mA (when the wavelength width of output light Δλ=2.0 nm). In this example, when drive current value 1op1=about 200 mA, light output P1=about 40 mW and P2=about 50 mW. The aforementioned stepwise change is caused by a mode hop phenomenon of the semiconductor laser, and when the external resonator is provided for the semiconductor laser, the phenomenon is more prominent and becomes an obstacle factor for obtaining a stable laser light source.

Meanwhile, since a laser light source adopting a semiconductor laser performing the ACC does not form a loop circuit, oscillation is avoidable. However, a problem that the light output gradually decreases due to deterioration of the semiconductor laser, itself, or the whole laser light source by electricity applied thereto is recognizable.

In view of the foregoing circumstances, the present disclosure is directed to obtain a laser light source that can achieve stable light output by suppressing unwanted oscillation.

A laser light source according to the present disclosure uses a semiconductor laser, as a light source, and the laser light source includes a light detector that detects light output from the semiconductor laser, a feedback circuit that receives a signal output from the light detector and sets a drive current of the semiconductor laser so that the light output indicated by the signal is within a target region, and a control circuit that sets the target region between a light output P2 and a light output P1 smaller than the light output P2.

In the aforementioned configuration, it is desirable that
0.01≤(P2−P1)/(P2+P1)≤0.1 is satisfied. Further, in the aforementioned configuration, it is also desirable that an external resonator is provided besides a resonator of the semiconductor laser. Further, in the aforementioned configuration, it is also desirable that a GaN-based semiconductor laser having an oscillation wavelength in the range of from 375 nm to 530 nm is adopted as the semiconductor laser.

In the aforementioned laser light source, it is desirable that an external resonator constituted by a mirror that returns a part of laser light output from the semiconductor laser toward the semiconductor laser and passes remaining laser light and an end surface of the semiconductor laser is included. Further, when the aforementioned external resonator is included, it is more desirable that a bandpass filter is inserted to a laser light path between the mirror and the semiconductor laser to narrow the wavelength of the laser light to a narrow band.

The laser light source of the present disclosure, configured as described above, is able to achieve stable light output by suppressing unwanted oscillation.

### BRIEF DESCRIPTION OF THE DRAWINGS

FIG. 1 is a schematic diagram illustrating a laser light source according to a first embodiment of the present disclosure.

FIG. 2 is a schematic diagram for explaining control of a semiconductor laser drive current in the laser light source illustrated in FIG. 1.

FIG. 3 is a graph showing a relationship between elapsed time and light output in the laser light source illustrated in FIG. 1.

FIG. 4 is a graph showing a relationship between light output and an optical noise amount in the laser light source illustrated in FIG. 1.

FIG. 5 is a schematic diagram showing a relationship between the drive current value and the light output from a laser light source related to the present disclosure.

FIG. 6 is a schematic diagram for explaining the relationship shown in FIG. 5 in more details.

FIG. 7 is a graph showing a relationship between elapsed time and light output in a laser light source other than the present disclosure.

FIG. 8 is a schematic diagram illustrating a laser light source according to a second embodiment of the present disclosure.

FIG. 9 is a schematic diagram showing a relationship between the drive current value and the light output value of a laser light source related to the present disclosure.

### DETAILED DESCRIPTION OF THE PREFERRED EMBODIMENTS

Next, embodiments of the present disclosure will be described with reference to the drawings.

### First Embodiment

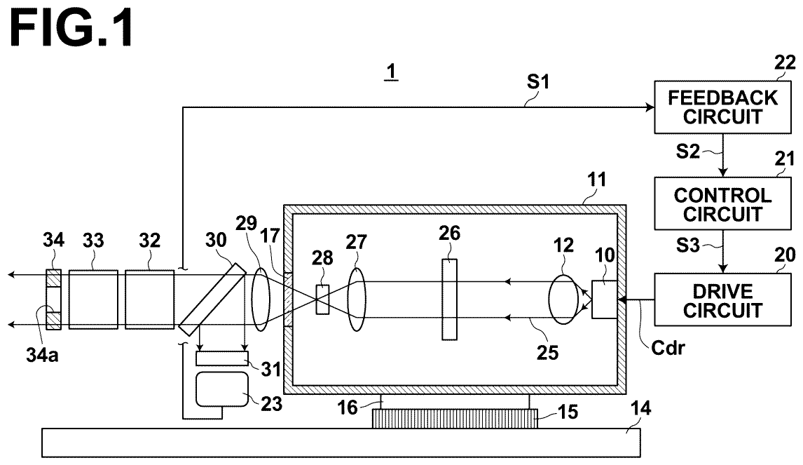

FIG. 1 is a schematic diagram illustrating the configuration of a laser light source 1 according to the first embodiment of the present disclosure. The laser light source 1 includes a semiconductor laser 10, as a light source, a box-shaped housing 11 with the semiconductor laser 10 secured to the inside thereof and a collimating lens 12. The collimating lens 12 is secured to the inside of the housing 11 like the semiconductor laser 10. The housing 11 is secured, via an adhesive layer 16, to a Peltier device 15 secured onto a base plate 14. Further, a light output window 17, constituted by a light transmissive member, is formed on one side of the housing 11 (the left side surface in the diagram).

Here, it is more desirable to mix beads into the adhesive layer 16 to be used for adhesion. For example, it is preferable that the material of the beads is ceramics and each bead has a true round shape with a diameter of 20 through 70 μm. When the ambient temperature of the laser light source 1 changes, if the Peltier device 15 is driven, a distortion of the Peltier device 15 occurs. However, if the beads are mixed, the distortion does not tend to transfer to the housing 11 via the adhesive layer 16. In other words, it is presumable that the mixed beads absorb the distortion of the Peltier device 15 and reduce a transfer of the distortion to the housing 11. If the housing 11 is distorted, the amount of light returned from a resonator mirror 28 to the semiconductor laser 10 changes, and therefore, the light out from the laser light source 1 changes. However, it is possible to suppress the fluctuation of the light output from the laser light source 1 even more by mixing the beads.

The semiconductor laser 10 is driven by drive current Cdr supplied by a drive circuit 20. The drive circuit 20 is connected to a control circuit 21, and the control circuit 21 is connected to a feedback circuit 22. A photodiode 23 is connected to the feedback circuit 22. The photodiode 23 detects light output from the semiconductor laser 10, and in one example, the photodiode 23 is arranged outside the housing 11. Further, a collimating lens 12 facing the semiconductor laser 10, and a narrow bandpass filter 26, a light collecting lens 27 and a resonator mirror 28, through which laser light 25 that has passed through the collimating lens 12 sequentially passes, are arranged in the housing 11.

Outside the housing 11, a collimating lens 29, through which the laser light 25 output from the light output window 17 via the resonator mirror 28 passes, a beam splitter 30, which reflects or passes the laser light 25 that has passed through the collimating lens 29, a diffusion plate 31, which diffuses the laser light 25 reflected by the beam splitter 30, a prism pair consisting of prisms 32, 33, which the laser light 25 passed through the beam splitter 30 enters, and a pinhole plate 34 having a pinhole 34a are arranged. The diffusion plate 31 is arranged in front of a light receiving surface of the photodiode 23 to diffuse the laser light 25 to be received by the photodiode 23.

Next, the action of the aforementioned configuration will be described. As an example, a GaN-based semiconductor laser (laser diode) having the oscillation wavelength of 488 nm is used as the semiconductor laser 10. In the semiconductor laser 10, cleaved surfaces of a laser medium constituting a front end surface and a back end surface of an optical waveguide, extending from left to right in the drawing, have a reflectance of about 0% and a reflectance of about 100%, respectively. Since light output from the optical waveguide made of the laser medium is naturally reflected at the back end surface of the laser medium and also reflected at the front end surface, the reflectance of which is not exactly 0%, reflection is repeated between the two end surfaces and laser oscillation is induced. In other words, the semiconductor laser 10, itself, is able to oscillate.

The laser light 25 generated in this manner is output forward (toward the left side in the drawing) from the semiconductor laser 10 in a spread light state. After the laser light 25 is collimated by the collimating lens 12, the wavelength of the laser light 25 is narrowed to a narrow band by the narrow bandpass filter 26, and the laser light 25 is focused by the focusing lens 27 and then enters the resonator mirror 28. A coating for partially reflecting the laser light 25 is provided on a front end surface of the resonator mirror 28, and this front end surface and the aforementioned back end surface of the semiconductor laser 10 also constitute a resonator (external resonator). In other words, this external resonator and the resonator of the semiconductor laser 10, itself, constitute a complex resonator.

Since the laser light source 1 of the present embodiment having the complex resonator structure has a function of locking the wavelength, the number of longitudinal modes of the oscillation wavelength of the semiconductor laser 10 is reduced, and a stable light source substantially without fluctuation of the oscillation wavelength is obtainable. To confirm this condition, experiments were carried out by using resonator mirrors 28 having various values of reflectance of 20%, 30%, 50%, 65% and 80%. When the value of reflectance is 20% or 30%, which is small, the amount of light returning to the semiconductor laser 10 is small. Therefore, the effect of external resonator is small, and the function of locking the wavelength, which suppresses the fluctuation of the oscillation wavelength, becomes weak, and the light output is increased. In contrast, when the value of reflectance of the resonator mirror 28 is 50%, 65% or 85%, which is large, the effect of locking the wavelength by the external resonator increases, but a disadvantage that the light output from the resonator mirror 28 decreases arises.

It is possible to realize the laser light source 1 regardless of the value of the reflectance of the resonator mirror 28. However, when the resonator mirror 28 having the reflectance of 65% is used by considering the balance between the light output and the wavelength locking, if the bandpass filter 26 having a half maximum width of 1.0 nm or 0.5 nm is used, it is possible to stably keep the state where the longitudinal mode of the oscillation wavelength is single. Here, the term “stably” means that the longitudinal mode of the oscillation is constantly kept in a single mode even if the drive current value of the semiconductor laser 10 changes or the ambient temperature of the laser light source 1 changes. Meanwhile, the term “unstable” means that the longitudinal mode is a single mode or a plurality of modes and the number of the longitudinal modes is not stable. The state becomes unstable if the half maximum width is greater than 2.0 nm. In the laser light source 1 of the present embodiment, the bandpass filter 26 having the half maximum width of 1.0 nm was used, which makes the longitudinal mode single, as described above. In measurement equipment, for example, such as a Raman scattering measurement device and a semiconductor wafer inspection device, which requires a strict accuracy of wavelength, such a laser light source having the single longitudinal mode of the oscillation wavelength is highly needed. Therefore, in such a laser light source for precise measurement, it is desirable that the half maximum width of the bandpass filter 26 is 1.0 nm or less.

The laser light 25 that has passed through the resonator mirror 28 is output to the outside of the housing 11 through the light output window 17. A part of the laser light 25 is reflected by the beam splitter 30 and received by the photodiode 23, and the remaining part passes through the beam splitter 30. The laser light 25 that has passed through the beam splitter 30 passes through the prism pair consisting of the prisms 32 and 33 and the pinhole 34a of the pinhole plate 34, and is used as light for measurement, for example, in various kinds of measurement devices.

In FIG. 1, the prisms 32 and 33 are illustrated as simple rectangles, but the actual prisms are a pair of wedge-shaped prisms, i.e., an anamorphic prism pair, which are observable as “wedge shapes” viewed in the vertical direction in FIG. 1. If this kind of anamorphic prism pair is used, even if the beam cross-sectional shape of the entering laser light 25 is oval, it is possible to output the laser light 25 having a true round cross-sectional shape. In an example of the present embodiment, when the laser light 25 having a beam diameter in the horizontal direction (the direction perpendicular to the paper surface of FIG. 1) is 1500 μm before passing through the prisms 32 and 33 was passed through the prisms 32 and 33, it was possible to change the beam diameter in the horizontal direction to 500 μm, which is the same as the beam diameter in the vertical direction (the direction from the top to the bottom of FIG. 1).

Especially, when the laser light 25 is used as the aforementioned light for measurement, the light output needs to be kept in a certain fixed range. Next, how this need is satisfied will be described. The photodiode 23 that has received a part of the laser light 25 outputs a light receiving signal S1. The light receiving signal S1 corresponds to the light intensity of the laser light 25, i.e., corresponds to the light output from the semiconductor laser 10, and is input to the feedback circuit 22. The feedback circuit 22 together with the control circuit 21 sets the drive current Cdr of the semiconductor laser 10 so that the light output from the semiconductor laser 10 indicated by the light receiving signal S1 is within a target region.

Specifically, the control circuit 21 sets the target region between the light output P2 and light output P1, which is smaller than P2, and sends a drive control signal S3 corresponding to a light intensity signal S2 (a signal after processing, such as amplification, has been performed on the light receiving signal S1) input from the feedback circuit 22 to the drive circuit 20. The drive control signal S3 decreases the drive current Cdr if the light output from the semiconductor laser 10, indicated by the light intensity signal S2, is larger than the light output P2. In contrast, the drive control signal S3 increases the drive current Cdr if the light output from the semiconductor laser 10 is smaller than the light output P1.

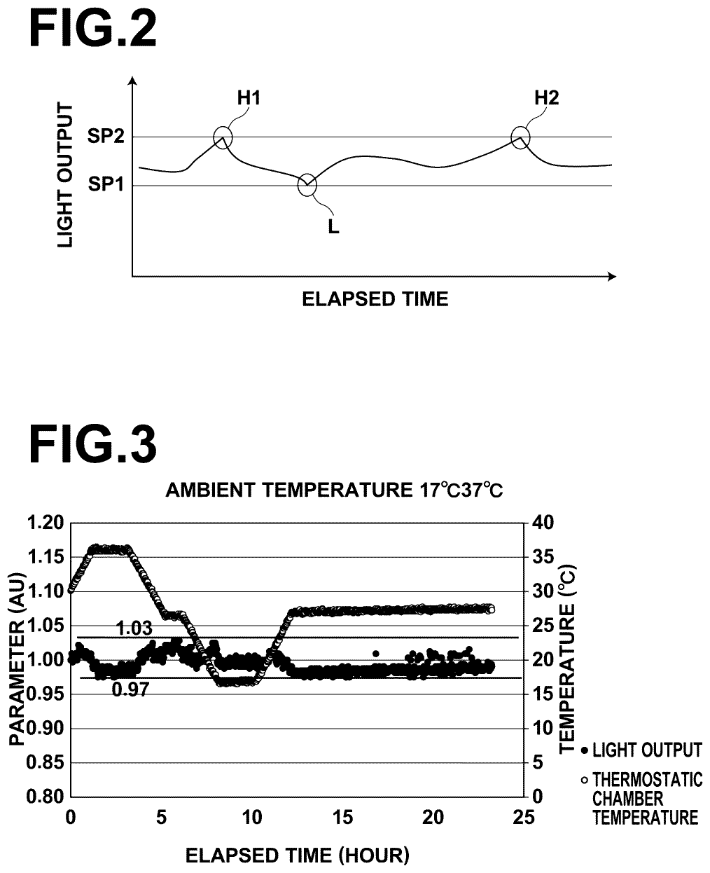

FIG. 2 illustrates what was described above so as to facilitate understanding. In the coordinate system illustrated in FIG. 2, the vertical axis represents the light output and the horizontal axis represents the elapsed time to the laser light source 1. FIG. 2 shows a change in the light intensity signal S2 as time passes, and the manner of change is schematically illustrated for the purpose of explanation. The elapsed time is the length of time passed while the light intensity signal S2 has exhibited a change. In sections H1 and H2 of FIG. 2, the light output from the semiconductor laser 10, indicated by the light intensity signal S2, increases as time passes and finally exceeds the predetermined light output P2. Then, the drive control signal S3 sent to the drive circuit 20 by the control circuit 21 lowers the drive current Cdr of the semiconductor laser 10 and the light output from the semiconductor laser 10 starts to decrease to be maintained at the light output P2 or lower.

Meanwhile, in section L of FIG. 2, the light output from the semiconductor laser 10, indicated by the light intensity signal S2, decreases as time passes and finally becomes lower than the predetermined light output P1. Then, the drive control signal S3 sent to the drive circuit 20 by the control circuit 21 increases the drive current Cdr of the semiconductor laser 10 and the light output from the semiconductor laser 10 starts to increase to be maintained at the light output P1 or higher. In this way, the effect of maintaining the light output from the semiconductor laser 10 always in the range of from the light output P1 to the light output P2 is achievable. Here, as described already, when beads have been mixed into the adhesive layer 16, the fluctuation of the light output from the laser light source 1 is suppressed even more. Accordingly, the light output from the laser light source 1 naturally tends neither to exceed the light output P2 or to become lower than the light output P1 in FIG. 2, and it can be said that the mixture of beads is desirable also to maintain the light output in the range of from the light output P1 to the light output P2.

The aforementioned confirmed result will be described with reference to FIG. 3. FIG. 3 shows a result of measuring the relationship between the light output and the elapsed time in the laser light source 1 of the present embodiment. In FIG. 3, the horizontal axis represents the elapsed time to the laser light source 1 and the vertical axis on the left side of the coordinate system represents the light output. In the coordinate system, many successive white circles represent a thermostatic chamber temperature for each elapsed time (in the unit of hour) and many successive black circles represent a light output for each elapsed time. When the relationship is measured, the whole laser light source 1 is placed in the thermostatic chamber and the light output is measured, and the thermostatic chamber temperature means the temperature of the thermostatic chamber. In FIG. 3, the thermostatic chamber temperature is represented by the vertical axis on the right side of the coordinate system. In the present example, the thermostatic chamber temperature, as the ambient temperature of the laser light source 1, was changed in the range of from 17° C. to 37° C. Further, the light output represented by the vertical axis on the left side is a relative value with respect to the light output of 1.00 when the thermostatic chamber temperature is 20° C. Here, when the light output is 1.00, the actual light output is about 50 mW.

As shown in FIG. 3, when the thermostatic chamber temperature changed, the light output also changed in response to the change, but even if the thermostatic chamber temperature changed stepwise greatly for the range of 20° C., the change of the light output remained relatively small between a minimum relative value of 0.97 and a maximum relative value of 1.03.

Since the control width was set at ±3% in the present embodiment, the fluctuation width of the light output from the laser light source 1 was also ±3%, but the setting may be modified in an arbitrary manner. Specifically, the control width may be set at ±1%, ±5% or ±10%. Setting of the control width at ±1% or less is possible, but when the fluctuation of the output from the laser light source 1 is large among variations if the set value is too small, there are cases where the fluctuation becomes large on the contrary. For example, when the control width is ±0.1%, the control acts frequently. Since the control range of 0.1% is small, overshooting and undershooting are repeated, and there are cases where the fluctuation width rather increases. As a result, the fluctuation width exceeds the set value of 0.1%. An appropriate value is about ±1% or greater. The upper limit is ±10% when a practical functionality is taken into consideration. If the upper limit is higher than that value, the fluctuation of the light output from the laser light source becomes large. This condition is represented by the following relational formula:

$$0.01 \leq ( P 2 - P 1 ) / ( P 2 + P 1 ) \leq 0.1 .$$

In this formula, the value of 0.01 corresponds to the fluctuation of ±1% and the value of 0.1 corresponds to the fluctuation of ±10%.

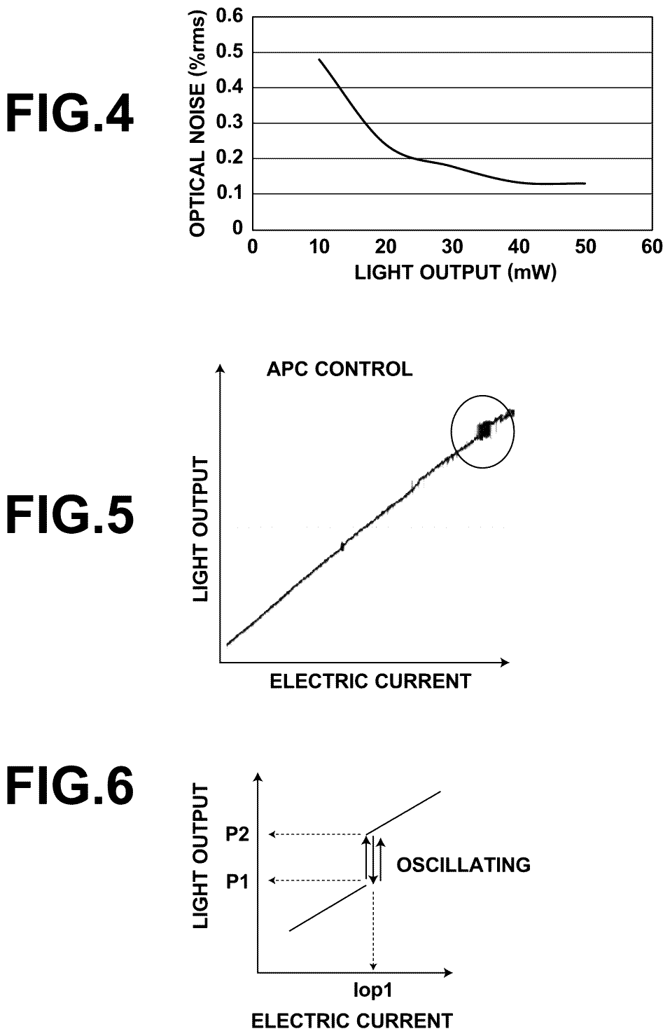

FIG. 4 is a graph showing the relationship between the light output and the generated optical noise in the laser light source 1 of the present embodiment. The horizontal axis represents the light output by the unit of mW, and the vertical axis represents the optical noise by the unit of % rms. In this relationship, even if the light output changes in the range of from 10 mW to 50 mW, the change of the optical noise remains approximately in the range of from 0.8% rms to 0.13% rms, which is relatively small.

Here, the optical noise will be described in detail. This kind of optical noise is roughly classified into an optical noise caused by a controller (driver), which drives the semiconductor laser 10, and an optical noise caused by the laser light source. The former optical noise is actually an electric noise and the latter optical noise is a noise of the laser light, itself. Since the former optical noise depends on the controller, the optical noise is not directly related to the present disclosure. However, since it is impossible to distinguish measurement data, themselves, based on the cause of the noise, the former electric noise is included in the optical noise. The latter optical noise requires deep consideration and includes various noises, for example, such as a thermal noise, an optical feedback noise, a mode hop noise, an interference noise and a quantum noise.

The present disclosure mainly tries to reduce the mode hop noise. The mode hop noise includes a noise caused by the external resonator and a noise caused by the semiconductor laser. In the laser light source according to the present disclosure, the mode hop noise caused by the external resonator does not impact on the optical noise, and causes no actual problem.

A resonator is formed at two cleaved end surfaces of a laser medium constituting the semiconductor laser, and the resonator is formed by these end surfaces. In a non-reflective semiconductor laser, a non-reflective coating is applied to an output end surface to make the reflectance substantially 0%. However, since the reflectance is not exactly 0%, a slight amount of light is returned, and the resonator is formed. Therefore, a mode hope noise of the semiconductor laser is generated. Since the semiconductor laser is made of semiconductor, the refractive index changes depending on the temperature and drive current. Therefore, it is extremely difficult to form a coating having a reflectance that is exactly 0%.

Next, comparative examples, which have not adopted the present disclosure, will be described.

### First Comparative Example

In the first comparative example, the drive circuit 20, control circuit 21 and feedback circuit 22 illustrated in FIG. 1, which achieve the aforementioned action, are not provided, but instead, a conventional APC (Automatic Power Control) circuit (not illustrated), which performs APC, is provided. In other words, in the laser light source of the first comparative example, for example, a light detector similar to the aforementioned photodiode 23 is provided, and a light detection signal output from the light detector is input to the APC circuit. The light detection signal corresponds to the laser light output from the semiconductor laser, which is not illustrated, and the APC circuit inputs a semiconductor laser drive control signal that makes the value of the light output a predetermined value to the semiconductor laser drive circuit. Through this process, drive control is performed on the semiconductor laser so that the laser light output therefrom becomes the predetermined value. In this way, the APC driven laser light source is able to achieve a constant light output, but a problem is recognized that oscillation is induced at a high speed control as a circuit loop is formed.

With reference to FIGS. 5 and 6, the aforementioned problem of oscillation induced in the APC driven laser light source will be described. When this kind of laser light source is APC driven, the relationship between the drive current value and the light output value of the laser light source is illustrated in FIG. 5, and a region where this relationship is repeated (the region surrounded by a circle in FIG. 5) is generated in some cases (for example, when scanned at the frequency=50 Hz). It is presumable that such a region is generated because oscillation occurs near a certain electric current value 1op1, and the light output is repeated at values between P1 and P2, as schematically illustrated in FIG. 6. Therefore, even if the laser light source is APC driven, the oscillation, itself, would remain.

### Second Comparative Example

In the second comparative example, the drive circuit 20, the control circuit 21 and the feedback circuit 22, illustrated in FIG. 1, are not provided, but instead, a conventional ACC (Automatic Current Control) circuit (not illustrated), which performs ACC, is provided. In other words, in the laser light source of the second comparative example, for example, a light detector similar to the aforementioned photodiode 23 is provided, and a light detection signal output from the light detector is input to the ACC circuit. The ACC circuit inputs, based on the light detection signal, a semiconductor laser drive control signal that makes the value of the drive current a predetermined value to the semiconductor laser drive circuit. Through this process, the semiconductor laser is controlled to be driven at a fixed electric current value. The laser light source using the ACC driven semiconductor laser in this manner does not form a loop circuit. Therefore, a problem of oscillation does not arise, but a problem that the light output gradually decreases due to deterioration caused by continuous driving of the semiconductor laser, itself, or continuous driving the laser light source including the semiconductor laser is recognizable. Further, this kind of laser light source is not able to suppress a sudden fluctuation caused by a mode hop.

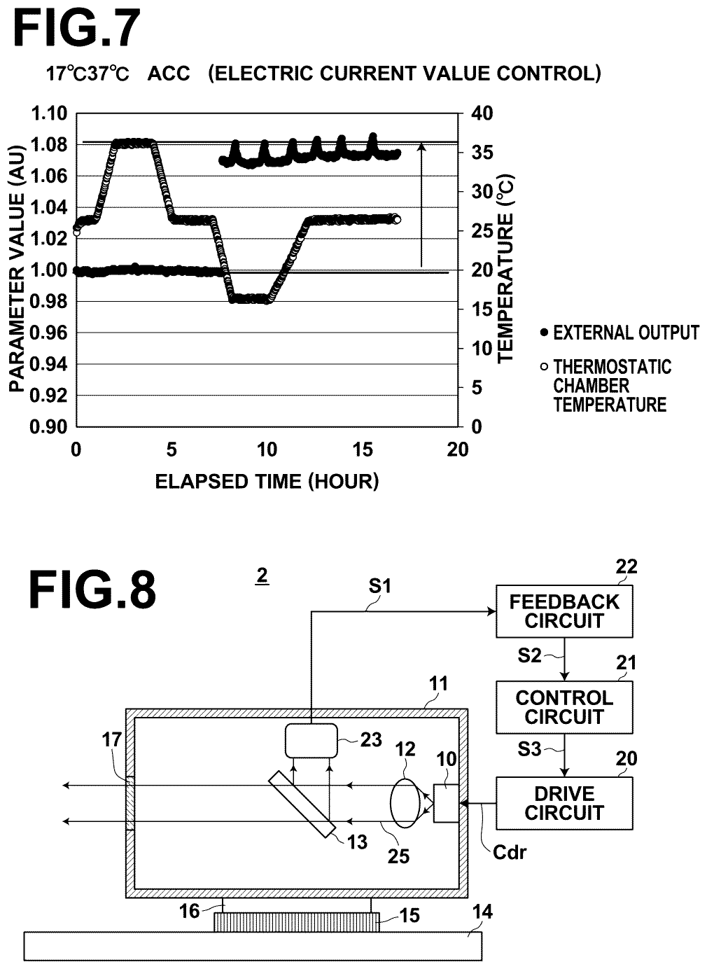

FIG. 7 shows, in a similar manner to FIG. 3, a relationship between light output and elapsed time in an ACC driven laser light source, as described above. The manner of illustration of FIG. 7 is similar to FIG. 3, and as shown in FIG. 7, when some change occurs in the laser light source, a sudden change in the output occurs. FIG. 7 shows a measurement result when the ambient temperature of the laser light source changed in the range of from 17° C. to 37° C. The light output was stable from the time of staring application of electricity to 8 hours after the start, but then, a mode hop of the semiconductor suddenly occurred, and a sharp fluctuation of output by about 8% occurred. As described, it is difficult to achieve stable light output by the ACC drive.

### Second Embodiment

Next, with reference to FIG. 8, a laser light source 2 according a second embodiment of the present disclosure will be described. FIG. 8 is a schematic diagram illustrating the configuration of the laser light source 2. Basically, the laser light source 2 includes elements constituting the laser light source 1 illustrated in FIG. 1, but the elements constituting the external resonator are excluded. In other words, the semiconductor laser 10 that is able to oscillate alone is adopted, as the light source. In FIG. 8, the same reference numerals as those used in FIG. 1 are assigned to the elements similar to those of FIG. 1, and redundant explanations are omitted.

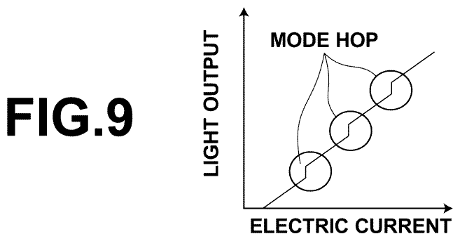

In some cases, the aforementioned mode hop of the semiconductor laser occurs also in the laser light source 2 illustrated in FIG. 8, and there is a risk of generation of an optical noise by the mode hop. Specifically, as shown in FIG. 9, in which the horizontal axis represents the drive current of the semiconductor laser and the vertical axis represents the light output from the semiconductor laser, the relationship between the drive current and the light output sharply changes in the regions indicated by circles in FIG. 9. When the feature that no external resonator is provided in the configuration of FIG. 8 is taken into consideration, it is considered that a mode hop is generated in the semiconductor laser, itself.

In the laser light source 2 having the aforementioned basic configuration, the drive circuit 20, control circuit 21, feedback circuit 22 and photodiode 23 similar to those illustrated in FIG. 1 are also provided, and the semiconductor laser 10 is driven in a similar manner to the one in the laser light source 1. Therefore, a similar effect achieved by the laser light source 1 is achievable also in the laser light source 2.

In the embodiments described so far, the GaN-based semiconductor laser having the oscillation wavelength of 488 nm is used as the semiconductor laser 10, but the semiconductor laser 10 is not limited to such a semiconductor laser. A GaN-based semiconductor laser having the oscillation wavelength in the range of from 375 nm to 530 nm and the like is also preferably usable.

What is claimed is:

1. A laser light source using a semiconductor laser, as a light source, the laser light source comprising:
a light detector that detects light output from the semiconductor laser;
a feedback circuit that receives a signal output from the light detector and sets a drive current of the semiconductor laser so that the light output indicated by the signal is within a target region; and
a control circuit that sets the target region between a light output P2 and a light output P1 smaller than the light output P2.

2. The laser light source according to claim 1,
wherein 0.01≤(P2−P1)/(P2+P1)≤0.1 is satisfied.

3. The laser light source according to claim 1,
wherein an external resonator is provided besides a resonator of the semiconductor laser.

4. The laser light source according to claim 1,
wherein the semiconductor laser is a GaN-based semiconductor laser having an oscillation wavelength in the range of from 375 nm to 530 nm.

5. The laser light source according to claim 1,
wherein an external resonator constituted by a mirror that returns a part of laser light output from the semiconductor laser toward the semiconductor laser and passes remaining laser light and an end surface of the semiconductor laser is included.

6. The laser light source according to claim 5,
wherein a bandpass filter is inserted to a laser light path between the mirror and the semiconductor laser and narrows the wavelength of the laser light to a narrow band.

7. The laser light source according to claim 6,
wherein the half maximum width of the bandpass filter is 1.0 nm or less.
